(19) United States
(12) Patent Application Publication
(10) Pub. No.: US 2025/0331310 A1
(43) Pub. Date: Oct. 23, 2025

(54) ELECTROSTATIC DISCHARGE SEMICONDUCTOR DEVICE AND MANUFACTURING METHOD THEREOF

(71) Applicant: Joulwatt Technology Co., Ltd., Hangzhou (CN)

(72) Inventor: Zhiqin DENG, Hangzhou (CN)

(21) Appl. No.: 19/176,499

(22) Filed: Apr. 11, 2025

(30) Foreign Application Priority Data
Apr. 17, 2024 (CN) 202410462741.5

(51) Int. Cl. H10D 89/60; H10D 10/00; H10D 10/01; H10D 10/60; H10D 62/10; H10D 62/60; H10D 84/01; H10D 84/60

(52) U.S. Cl. CPC H10D 89/713; H10D 10/241; H10D 10/60; H10D 62/108; H10D 62/124; H10D 62/60; H10D 84/645; H10D 10/061; H10D 84/0112

(57) ABSTRACT

An electrostatic discharge semiconductor device is disclosed and comprises: a first well region of a first doping type, extending from the surface of an epitaxial layer to the surface of the substrate; a second well region and a third well region of a second doping type; a fourth well region of the second doping type; a fifth well region and a sixth well region have a first doping type; a first injection region and a second injection region, spaced apart in each well region. The second injection region in the second and third well regions is connected to a cathode, and the first and second injection regions in the fourth well region are connected to an anode. The electrostatic discharge semiconductor device enhances its electrostatic protection capability by adjusting the avalanche breakdown voltage between the floating fifth and sixth well regions and the triggering voltage of the device.

### CROSS-REFERENCE TO RELATED APPLICATIONS

This present disclosure claims priority to a Chinese patent application No. 2024104627415, filed on Apr. 17, 2024, and entitled “electrostatic discharge semiconductor device and manufacturing method thereof”, the entire contents of which are incorporated herein by reference, including the specification, claims, drawings and abstract.

### FIELD

The present disclosure relates to the field of semiconductor technology, more particularly, to an electrostatic discharge semiconductor device and a manufacturing method thereof.

### BACKGROUND

ESD (Electro Static Discharge) is an objective natural phenomenon that accompanies the entire product cycle. ESD is not easily perceived by human bodies, but it poses a serious threat to integrated circuit products. During the manufacturing, packaging, testing, and application stages of chips, the external environment and internal structures accumulate a certain amount of charge, and they can be threatened by static electricity at any time. Therefore, ESD protection devices need to be placed at each pin during chip design. LDMOS (laterally diffused metal oxide semiconductor) or SCR (Silicon Controlled Rectifier) structures are often used as ESD protection devices.

FIG. 1 shows a cross-sectional schematic diagram of controllable silicon electrostatic protection semiconductor device in a prior art, and FIG. 2 shows a schematic diagram of the circuit structure corresponding to the SCR structure of FIG. 1. As shown in FIGS. 1 and 2, the electrostatic protection device of the SCR structure comprises a P-type substrate 10, an N-type well region 30 and a P-type well region 20 located on the upper part of the substrate 10. A P+ injection region 14 and an N+ injection region 13 are formed in the N-type well region 30, and a P+ injection region 12 and an N+ injection region 11 are formed in the P-type well region 20. The cathode is connected from P+ injection region 12 and N+ injection region 11, and the anode is connected from P+ injection region 14 and N+ injection region 13. The SCR path of traditional unidirectional SCR devices consists of P+ injection region 14, N-type well region 30, P-type well region 20, and N+ injection region 11. When an ESD pulse arrives, a forward pulse appears at the anode terminal. The reverse biased PN junction composed of N-type well region 30 and P-type well region 20 will undergo avalanche breakdown, thus generating a large number of carriers that continuously flow through the parasitic well resistance Rp on P-type well region 20, increasing the voltage drop Vbe between the base and emitter of the lateral parasitic NPN triode. The lateral parasitic NPN triode is triggered and operates in the amplification region until Vbe exceeds 0.7V. The amplified collector current will flow into the base of the parasitic PNP transistor, and finally the parasitic PNP t triode will turn on. At this point, the parasitic NPN triode and parasitic PNP triode form effective positive feedback, and finally a low resistance lateral SCR discharge path is formed, with a high trigger voltage, low holding voltage, and easy occurrence of latch up effect. Therefore, the current electrostatic protection devices with SCR structures have poor electrostatic protection capabilities.

### SUMMARY

In view of the above issues, the purpose of the present disclosure is to provide an electrostatic discharge semiconductor device and a manufacturing method thereof to solve the problems in the prior art.

According to an aspect of the present disclosure, an electrostatic discharge semiconductor device is provided, comprising: a substrate of a first doping type; an epitaxial layer, located above the substrate; a first well region of a first doping type, extending from the surface of the epitaxial layer to the surface of the substrate; a second well region and a third well region of a second doping type, extending from the surface of the epitaxial layer to the surface of the substrate, and located on both sides of the first well region respectively and separated from the first well region; a fourth well region of the second doping type, extending from the surface of the first well region to the internal and separated from the substrate; a fifth well region and a sixth well regions have the first doping type, extending from the surface of the first well region to the internal and separated from the substrate; the fifth well region and the sixth well region are symmetrically distributed on both sides of the fourth well region and separated from the fourth well region; and a first injection region and a second injection region, spaced apart above the fourth well region, and having a first doping type and a second doping type, respectively; wherein the second injection region is distributed in both the second well rejoin and the third well rejoin and connected to a cathode, and the first injection region and second injection region in the fourth well region are connected to an anode.

Optionally, an avalanche breakdown voltage between the fifth well region and the fourth well region decreases as the distance between the fifth well region and the fourth well region decreases;

an avalanche breakdown voltage between the sixth well region and the fourth well region decreases as the distance between the sixth well region and the fourth well region decreases;

a trigger voltage of the electrostatic discharge semiconductor device decreases as the distance between the fifth/sixth well region and the fourth well region decreases.

Optionally, during operation of the electrostatic discharge semiconductor device, a controllable silicon structure composed of the first injection region in the fourth well region, the fourth well region, the first well region, the fifth well region and the sixth well region, the second well region and the third well region, and the second injection region in the second well region and the third well region is turned on to form a first current discharge path from the anode to the cathode.

Optionally, the electrostatic discharge semiconductor device further comprises: a buried layer of a second doping type, located in the upper part of the substrate and in contact with the first well region to the third well region; the first injection region has the highest doping concentration among all regions of the first doping type, while the second injection region has the highest doping concentration among all regions of the second doping type; the doping concentration of the buried layer is second only to the one with a higher doping concentration among the first injection region and second injection region.

Optionally, during operation of the electrostatic discharge semiconductor device, the controllable silicon structure composed of the first injection region in the fourth well region, the fourth well region, the first well region, the buried layer, the second well region and the third well region, and the second injection region in the second well region and the third well region is turned on to form a second current discharge path from the anode to the cathode.

Optionally, when the electrostatic discharge semiconductor device receives an electrostatic pulse, the first current discharge path is turned on before the second current discharge path, and the current on the first current discharge path is smaller than the current on the second current discharge path.

Optionally, the first injection region is distributed in both the fifth well region and the sixth well region, and the doping concentration of the first injection region in the fifth well region and the sixth well region is greater than the doping concentration of the fifth well region and the sixth well region, and the doping concentration of the fifth well region and the sixth well region is greater than the doping concentration of the first well region.

Optionally, the electrostatic discharge semiconductor device further comprises: a field oxide layer, distributed between the first injection region and the second injection region of each well region of the electrostatic discharge semiconductor device.

Optionally, the electrostatic discharge semiconductor device is of a dual interdigitated structure.

Optionally, the first doping type is P-type doping, while the second doping type is N-type doping.

According to another aspect of the present disclosure, a method for manufacturing an electrostatic discharge semiconductor device is provided, comprising: forming a substrate of a first doping type and a buried layer of a second doping type located in the upper part within the substrate; forming an epitaxial layer located above the substrate, the epitaxial layer covering the buried layer; forming a first well region of a first doping type extending inward from the surface of the epitaxial layer and extending to the surface of the buried layer; forming a second well region and a third well region of a second doping type extending from the surface of the epitaxial layer to the interior and extending to the surface of the buried layer, the second well region and the third well region being located on both sides of the first well region and separated from the first well region, respectively; forming a fourth well region of a second doping type extending inward from the surface of the first well region and separated from the buried layer; forming a fifth well region and a sixth well region of a first doping type extending from the surface of the first well region to the interior and separated from the buried layer, the fifth well region and the sixth well region being symmetrically distributed on both sides of the fourth well region and separated from the fourth well region; forming a plurality of spaced field oxide layers located above and outside the epitaxial layer;

and forming a plurality of spaced first injection regions and second injection regions located within each well region with the field oxide layer as an interval, and the first injection region and the second injection regions are of the first doping type and the second doping type, respectively, wherein, the second injection region is distributed in both the second well region and the third well region and connected to the cathode, and the first injection region and the second injection region in the fourth well region are both connected to the anode.

According to another aspect of the present disclosure, an integrated circuit is provided, comprising the above electrostatic discharge semiconductor device.

In the electrostatic discharge semiconductor device and the manufacturing method thereof provided by the present disclosure, only a second injection region is set in the second well region and the third well region, and no first injection region is set, thereby saving a resistor structure in the SCR structure. Moreover, by setting up the floating fifth well region and the floating sixth well region, the ion doping concentration in the first well region outside the fourth well region can be increased, the carrier migration efficiency on the device surface can be reduced, the current amplification factor can be reduced, and the holding voltage can be increased. By adjusting the distance between the fifth well region and sixth well region and the fourth well region, the avalanche breakdown voltage between the well regions can be adjusted to regulate the triggering voltage of the device. Therefore, the electrostatic protection capability of electrostatic discharge semiconductor device is enhanced, device size is reduced, and manufacturing processes are simplified. Furthermore, the shorter the distance between the fifth well region and the fourth well region, the shorter the distance between the sixth well region and the fourth well region, the lower the avalanche breakdown voltage and the triggering voltage of the electrostatic discharge semiconductor device, the better the device protection performance, making it suitable for electrostatic protection in the low voltage range.

Further, a heavily doped buried layer is formed on the upper part of the substrate of the electrostatic discharge semiconductor device, so that a longitudinal SCR current discharge path (second current discharge path) can be formed on the basis of the original SCR transverse current discharge path (first current discharge path), and the longitudinal SCR current discharge path can improve the holding voltage of SCR conduction. Due to the heavy doping of the buried layer, the longitudinal second current discharge path gradually becomes the dominant current discharge path, achieving current discharge inside the device and avoiding the accumulation of discharge heat on the device surface. Moreover, the buried layer and substrate, as well as the second and third well regions and the epitaxial layer, provide good internal and external isolation for the device to prevent leakage.

Further, a first injection region is set on the upper part of the floating fifth well region and sixth well region, to make the doping concentration in the fifth well region and sixth well region increase, making the first current discharge path closer to the substrate, thereby extending the current discharge path and improving the holding voltage of the device.

Further, the electrostatic discharge semiconductor devices uses a dual interdigitated structure to achieve layout symmetry, which improves the device's failure current and enhances its electrostatic protection performance.

### BRIEF DESCRIPTION OF THE DRAWINGS

The above and other objectives, features, and advantages of the present disclosure will become clearer through the following description of embodiments of the present disclosure with reference to the accompanying drawings.

FIG. 1 shows a cross-sectional schematic diagram of a prior art controllable silicon electrostatic protection semiconductor device;

FIG. 2 shows a schematic diagram of the circuit structure corresponding to the SCR structure in FIG. 1;

FIG. 3 shows a schematic cross-sectional view of an electrostatic discharge semiconductor device according to an embodiment of the present disclosure;

FIG. 4 shows a schematic diagram of the circuit structure corresponding to the SCR structure in FIG. 3;

FIGS. 5A-5D show cross-sectional schematic diagrams of various stages of the manufacturing method of the electrostatic discharge semiconductor device according to an embodiment of the present disclosure.

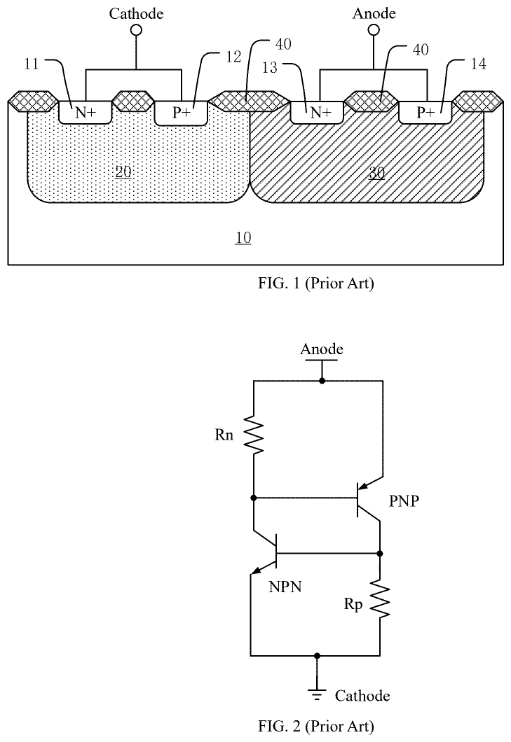

### DETAILED DESCRIPTION

Various embodiments of the present disclosure will be described in more details below with reference to the accompanying drawings. In each accompanying drawing, the same elements are denoted by the same or similar reference numerals. For clarity, the various parts in the accompanying drawings are not drawn to scale. In addition, some well-known parts may not be shown. For simplicity, the semiconductor structure obtained after several steps can be described in one drawing.

When describing the structure of a device, for a layer or region as being located “above” or “up” another layer or region, it can refer to being directly located above another layer or region, or containing other layers or regions between the layer and another layer or region. Moreover, if the device is flipped, that layer or region will be located “below” or “under” another layer or region. In this application, the term “semiconductor structure” refers to the collective term for the entire semiconductor structure formed in various steps of manufacturing semiconductor devices, including all layers or regions that have already been formed.

Unless otherwise specified in the following text, each layer or region of a semiconductor device may be composed of materials known to those skilled in the art. Semiconductor materials include, e.g., groups III-V semiconductors such as GaAs, InP, GaN, SiC, and group IV semiconductors, e.g., Si and Ge. Gate conductors and electrode layers can be formed of various conductive materials, such as metal layers, doped polycrystalline silicon layers, or stacked gate conductors including metal layers and doped polycrystalline silicon layers, or other conductive materials, such as TaC, TiN, TaSiN, HfSiN, TiSiN, TiCN, TaAlC, TiAlN, TaN, PtSix, Ni3Si, Pt, Ru, W, and combination with various conductive materials mentioned above.

The specific embodiments of the present disclosure will be further described in detail with reference to the accompanying drawings and examples.

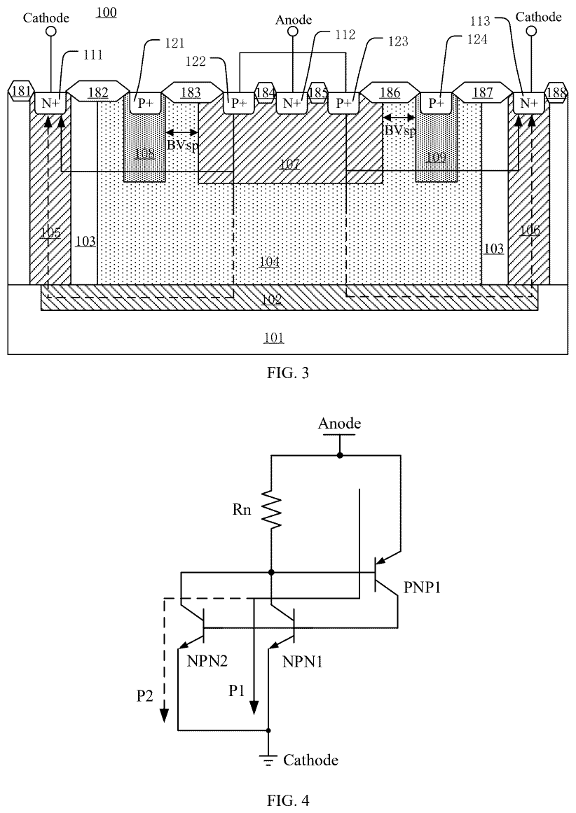

FIG. 3 shows a schematic cross-sectional view of an electrostatic discharge semiconductor device according to an embodiment of the present disclosure, and FIG. 4 shows a schematic circuit structure corresponding to the SCR structure of FIG. 3.

As shown in FIG. 3, the electrostatic discharge semiconductor device 100 of this embodiment comprises a substrate 101, a buried layer 102 located in the upper part of the substrate 101, and an epitaxial layer 103 located above the substrate 101. The substrate 101 has a first doping type, and the buried layer 102 has a second doping type. The buried layer 102 is located inside the substrate 101 and at the top of the substrate 101. The upper surface of the buried layer 102 is flush with the upper surface of the substrate 101. In this embodiment, the first doping type may be P-type doping, and the second doping type may be N-type doping. Of course, in other embodiments, the first doping type can also be N-type doping, and the second doping type can also be P-type doping. The epitaxial layer 103 covers the buried layer 102, and the epitaxial layer 103 can be P-type doped or N-type doped. In this embodiment, the epitaxial layer 103 is, for example, P-type doping.

Furthermore, the epitaxial layer 103 is distributed with a first well region 104, a second well region 105, and a third well region 106. The first well region 104, the second well region 105, and the third well region 106 all extend inward from the upper surface of the epitaxial layer 103, and the bottom is in contact with the buried layer 102, that is, the injection depth of the first well region 104, the second well region 105, and the third well region 106 is the same as the thickness of the epitaxial layer 103. The first well region 104 has a first doping type, such as P-type doping, while the second well region 105 and the third well region 106 have a second doping type, such as N-type doping. That is, the first well region 104 is a P-type well region, and the second well region 105 and the third well region 106 are N-type well regions. Moreover, in the lateral direction, the first well region 104 is distributed in the middle position of the epitaxial layer 103, while the second well region 105 and the third well region 106 are distributed on both sides of the first well region 104 and separated from the region by a certain distance. The second well region 105 and the third well region 106 are symmetrically distributed on both sides of the first well region 104, and the distance between second well region 105 and the first well region 104 and the distance between the third well and the first well 104 can be represented by BVsp.

Furthermore, the first well region 104 is also distributed with the fourth well regions 107, the fifth well regions 108, and the sixth well regions 109. The fourth well region 107, the fifth well region 108, and the sixth well region 109 all extend inward from the upper surface of the first well region 104, and are separated from the buried layer 102 at the bottom, that is, the injection depth of the fourth well region 107, the fifth well region 108, and the sixth well region 109 is smaller than that of the first well region 104. Moreover, the injection depths of the fourth well region 107, the fifth well region 108, and the sixth well region 109 can be the same. In this embodiment, the fourth well region 107 has a second doping type, such as N-type doping, while the fifth well region 108 and the sixth well region 109 have a first doping type, such as P-type doping. That is, the fifth well region 108 and the sixth well region 109 are P-type well regions, and the fourth well region 107 is an N-type well region. Moreover, in the lateral direction, the fourth well region 107 is distributed in the middle of the first well region 104, while the fifth well region 108 and the sixth well region 109 are distributed on both sides of the fourth well region 107 and separated from it by a certain distance. The fifth well region 108 and the sixth well region 109 are symmetrically distributed on both sides of the fourth well region 107, for example

The fourth well region 107 is distributed with a first injection region and a second injection region. The first injection region and the second injection region have a first doping type and a second doping type, respectively. That is, the first injection region can be a P+ injection region, and the second injection region can be an N+ injection region. Within the fourth well region 107, there are spaced P+ injection regions 122, N+ injection regions 112, and P+ injection regions 123. There are N+ injection regions 111 distributed in the second well region 105, and N+ injection regions 113 distributed in the third well region 106. The injection regions are formed at the upper part of each well region and can be formed by injecting from the surface of the well region to the inside. There are also a plurality of field oxide layers distributed among the gaps in each well region and injection region, e.g., field oxide layer 181, field oxide layer 182, field oxide layer 183, field oxide layer 184, field oxide layer 185, field oxide layer 186, field oxide layer 187, and field oxide layer 188. In addition, the N+ injection region 111 in the second well region 105 and the N+ injection region 113 in the third well region 106 are connected to the cathode, while the P+ injection regions 122, 112, and 123 in the fourth well region 107 are all connected to the anode. The fifth well region 108 and the sixth well region 109 are floating without circuit connections, and they are neither connected to the cathode nor the anode.

In this embodiment, the electrostatic discharge semiconductor device 100, for example, uses a dual interdigitated structure to achieve layout symmetry and enhance failure current. So, the electrostatic discharge semiconductor device 100 of this embodiment can be symmetrically distributed with the fourth well region 107 as the center, or with the N+ injection region 112 as the symmetrical center, forming a left-right symmetrical distribution.

FIG. 4 shows the SCR circuit structure corresponding to FIG. 3. Since it is a dual interdigitated device, this embodiment will explain first from the right side. As shown in FIG. 4, when a forward pulse arrives, a positive voltage is generated on the anode. The electrostatic discharge semiconductor device 100 forms a PNP parasitic triode PNP1 from the P+ injection region 123 in the fourth well region 107, the fourth well region 107, and the first well region 104, or forms a PNP parasitic triode PNP1 from the P+ injection region 123 in the fourth well region 107, the fourth well region 107, the first well region 104, and the sixth well region 109. The NPN parasitic triode NPN1 is formed by the fourth well region 107, the first well region 104, the epitaxial layer 103, the third well region 106, and the N+ injection region 113 within the third well region 106, or by the fourth well region 107, the first well region 104, the sixth well region 109, the epitaxial layer 103, the third well region 106, and the N+ injection region 113 within the third well region 106. Parasitic well resistance Rn is generated in the fourth well region 107. The forward voltage on the anode raises the voltage across resistor Rn, causing PNP1 to turn on and raising the base current of NPN1, and NPN1 is also turned on. That is, the thyristor structure composed of the P+ injection region 123 in the fourth well region 107, the fourth well region 107, the first well region 104, (the sixth well region 109), the third well region 106, and the N+ injection region 113 in the third well region 106 is turned on to form a P-N-P-N SCR current discharge path from the anode to the cathode. The first current discharge path P1 from the anode to the cathode is shown by the solid arrow in FIG. 4. When there is an electrostatic pulse on the cathode, due to the floating of the fifth well region 108 and the sixth well region 109, an additional diode path needs to be established from the cathode to the anode to enhance the reverse withstand voltage. Moreover, in this embodiment, since the third well region 106 only has an N+ injection region without a P+ injection region, compared with the SCR structure shown in FIG. 2, a well resistor Rp can be omitted, thereby reducing the device size and manufacturing cost.

In addition, the presence of the fifth well region 108 and the sixth well region 109 can increase the ion doping concentration in the first well region 104 outside the fourth well region 107, reduce the carrier migration efficiency on the device surface, decrease the current amplification factor, and increase the holding voltage. By adjusting the distance BVsp between the fifth well region 108 (the sixth well region 109) and the fourth well region 107, the avalanche breakdown voltage between the well regions and the trigger voltage when the SCR is turned on can also be adjusted. Specifically, the avalanche breakdown voltage between the fifth well region 108 (sixth well region 109) and the fourth well region 107, as well as the trigger voltage of the device decrease as the distance BVsp decreases. That is, the larger the distance BVsp between the fifth well region 108 (the sixth well region 109) and fourth well region 107, the higher the avalanche breakdown voltage and device trigger voltage. In contrast, the smaller the distance BVsp between the fifth well region 108 (sixth well region 109) and fourth well region 107, the lower the avalanche breakdown voltage and the device trigger voltage. Thus, the electrostatic discharge semiconductor device can be applied to different voltage ports, for example, they can be applied in low voltage protection environments of 5V-50V.

Furthermore, in FIG. 3, the electrostatic discharge semiconductor device 100 of this embodiment has a P+ injection region 121 distributed within the fifth well region 108 and P+ injection region 124 distributed within the sixth well region 109. In this embodiment, the doping concentration of all P+ injection regions may be the same, and the doping concentration of all N+ injection regions may be the same. Moreover, among all regions with the first doping type (including well regions, injection regions, drift regions, and substrates), the doping concentration of the P+ region is the highest. Among all regions with the second doping type (including well regions, injection regions, buried layers, and epitaxial layers), the doping concentration of the N+ injection region is also the highest. Specially, the doping concentration of P+ injection regions 121 and 124 is higher than that of the fifth well region 108 and the sixth well region 109, and the doping concentration of the fifth well region 108 and the sixth well region 109 is higher than that of the first well region 104. The presence of the higher concentration P+ injection region 124 (121) hinders the lateral flow of electrons in the SCR path, causing the first current discharge path P1 to move towards the substrate 101, i.e. extending closer to the substrate. As a result, the path of the first current discharge path P1 is extended, causing the triggering voltage of the device to rise.

Furthermore, the doping concentration of the buried layer 102 located in the substrate 101 is second only to the higher doping concentration of the first injection region and the second injection region, that is, the doping concentration of the buried layer 102 is second only to the injection region with the highest doping concentration. Since there is a heavily doped buried layer 102 in the substrate 101, this buried layer 102 provides the basis for a longitudinal current discharge path. The NPN parasitic triode NPN2 is formed by the fourth well region 107, the first well region 104, the buried layer 102, the third well region 106, and the N+ injection region 113 within the third well region 106. When there is an electrostatic pulse at the anode, the thyristor structure composed of the P+ injection region 123 in the fourth well region 107, the fourth well region 107, the first well region 104, the buried layer 102, the third well region 106, and the N+ injection region 113 in the third well region 106 can also conduct to form a second current discharge path P2 from the anode to the cathode, as shown by the dashed arrow in FIG. 3. The first current discharge path P1 is a transverse path, and the second current discharge path P2 is a longitudinal path. In this embodiment, when the electrostatic discharge semiconductor device 100 receives an electrostatic pulse, the first current discharge path P1 is turned on before the second current discharge path P2. After it is turned on, due to the heavily doped nature of the buried layer, the base current amplification factor of parasitic triode NPN2 is smaller than that of parasitic triode NPN1. Therefore, the current on the first current discharge path P1 is smaller than that on the second current discharge path P2, making the second current discharge path P2 the dominant current discharge path, and the current path is prolonged, and thus the holding voltage of the device is high. Moreover, since the longitudinal second current discharge path becomes the dominant path, current discharge is achieved inside the device, avoiding the concentration of discharge heat on the device surface and improving heat distribution, thus increasing the failure current of the device.

The above takes the right side structure of the semiconductor device as an example. Due to the symmetrical structure of the electrostatic discharge semiconductor device 100, the left side actually forms the same circuit structure as that in FIG. 4. A corresponding current discharge path is shown in FIG. 3, and it will not be described again here.

Furthermore, the buried layer 102 and substrate 101, the second well region 105 and the external epitaxial layer 103, the third well region 106 and the external epitaxial layer 103 provide internal and external isolation of the device, enabling it to have good electrostatic protection and prevent leakage.

In summary, the electrostatic discharge semiconductor device of this embodiment increases the doping concentration in the region by the floating fifth and sixth well regions, reduces the surface carrier migration efficiency of the device, decreases the current amplification factor, prolongs the current discharge path, and improves the holding voltage of the device. Moreover, by adjusting the distance between the fifth well region (the sixth well region) and the fourth well region, the avalanche breakdown voltage between the well regions and the holding voltage of the device can also be adjusted, making the device applicable to ports in different voltage ranges. The formation of P+ injection regions in the fifth well region and sixth well region prolongs the current discharge path, further enhancing the holding voltage of the device. Due to the presence of the heavily doped buried layer, a longitudinal second current discharge path can also be formed, which, in conjunction with the first current discharge path, enhances the holding voltage of the device. The second current discharge path is a longitudinal path, and the longitudinal path, as the dominant discharge path, can improve the internal heat distribution of the device, avoid heat concentration on the surface of the device, and increase the failure current. The electrostatic discharge semiconductor device of this embodiment can effectively avoid the risks of early circuit breakdown caused by high triggering voltage and device entering the latch due to low holding voltage.

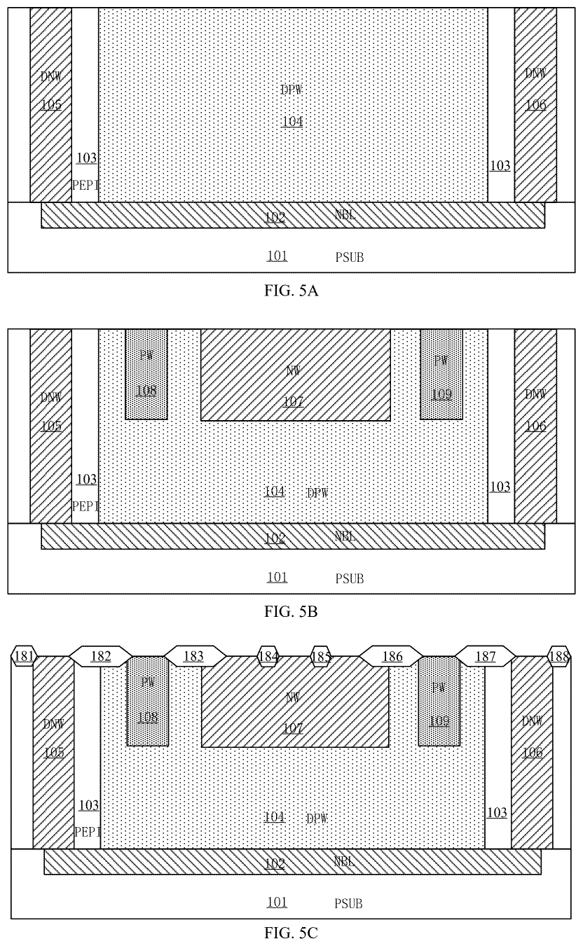

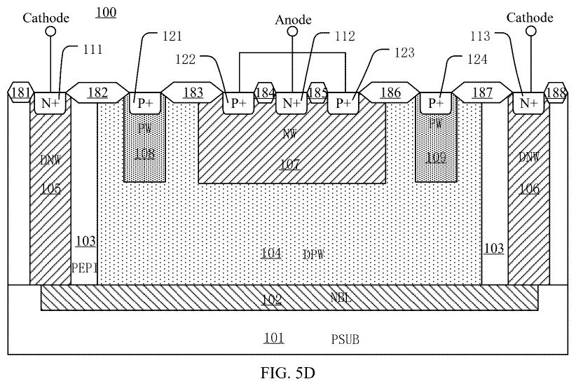

FIGS. 5A-5D show cross-sectional schematic diagrams of various stages of the manufacturing method of the electrostatic discharge semiconductor device according to an embodiment of the present disclosure. The semiconductor device shown in FIG. 3 is fabricated by the process steps of FIGS. 5A-5D to further enhance the electrostatic protection capability of the semiconductor device. The manufacturing method of the electrostatic discharge semiconductor device in the embodiment of the present application will be introduced in conjunction with FIGS. 5A-5D.

As shown in FIG. 5A, first, a substrate 101 with a first doping type and a buried layer 102 with a second doping type located in the upper part of the substrate 101 are formed.

Specifically, substrate 101 is a P-type doped silicon substrate P-SUB. The buried layer 102 is formed inside the substrate 101, which is an N-type doped layer structure NBL located at the upper part of the substrate 101. The upper surface of the buried layer 102 is, for example, flush with the upper surface of the substrate 101. Next, an epitaxial layer is formed above the substrate 101, and the epitaxial layer 103 covers he buried layer 102. The epitaxial layer 103 can be either N-type doped or P-type doped. Here, the P-type doped epitaxial layer 103 (PEPI) is taken as an example for illustration. Then, a well region injection is performed along the surface of the epitaxial layer 101, forming a first well region 104 (DPW) with the first doping type and extending inward from the surface of the epitaxial layer 103 and extending to the surface of the buried layer 102, and a second well region 105 (DNW) and a third well region 106 (DNW) with a second doping type are formed, which extend from the surface of the epitaxial layer 103 to the interior and extending to the surface of the buried layer 102. That is, the depths of the first well region 104, the second well region 105, and the third well region 106 can be consistent and the same as the thickness of the epitaxial layer 103. The first well region 104 is distributed in the middle position, and the second well region 105 and the third well region 106 are located on both sides of the first well region 104 and spaced from it by a certain distance. The electrostatic discharge semiconductor structure of this embodiment is a dual interdigitated structure, and here the second well region 105 and the third well region 106 are symmetrically distributed on both sides of the first well region 104, and the lateral width of the second well region 105 and the third well region 106 is smaller than that of the first well region 104.

Furthermore, as shown in FIG. 5B, a fourth well region 107 (NW) with a second doping type is formed within the first well region 104, which extends inward from the surface of the first well region 104 and is separated from the buried layer 102. A fifth well region 108 (PW) and a sixth well region 109 (PW) with the first doping type that extend inward from the surface of the first well region 104 are formed and are separated from the buried layer 102. The fourth well region 107 to the sixth well region 109 are all distributed within the first well region 104, and the bottoms of the three well regions are separated from the buried layer 102 by a certain distance, that is, the doping depths of the fourth well region 107 to the sixth well region 109 are smaller than that of the first well region 104. The fourth well region 107 is distributed in the middle position, and the fifth well region 108 and the sixth well region 109 are symmetrically distributed on both sides of the fourth well region 107 and separated from it by a certain distance.

Next, as shown in FIG. 5C, a plurality of spaced field oxide layers are formed above and outside the epitaxial layer 103. Specifically, field oxygen isolation is performed on the surface of epitaxial layer 103, i.e., forming a plurality of mutually isolated field oxide layers, such as field oxide layer 181, field oxide layer 182, field oxide layer 183, field oxide layer 184, field oxide layer 185, field oxide layer 186, field oxide layer 187, and field oxide layer 188. The formation of the field oxide layers use conventional processes, such as depositing an oxide layer on the surface of the epitaxial layer 103, then depositing a hard mask, etching using the mask, and finally growing field oxygen at high temperature, and removing the hard mask. The specific process are not described in detail.

Next, as shown in FIG. 5D, plural spaced first and second injection regions located within each well region are formed with the above a plurality of field oxide layers as intervals. The first injection region (P+ injection region) and the second injection region (N+ injection region) have the first doping type and the second doping type, respectively. Specifically, P+ or N+ injection is performed along the gaps plural field oxide layers in each well region to form a plurality of P+ or N+ injection regions. For example, N+ injection region 111 is formed in the second well region 105 (DNW), P+ injection region 121 is formed in the fifth well region 108 (PW), P+ injection region 122, N+ injection region 112, and P+ injection region 123 are formed in the fourth well region 107 (NW), P+ injection region 124 is formed in the sixth well region 109 (PW), and N+ injection region 113 is formed in the third well region 106 (DNW).

Furthermore, the anode and cathode of the semiconductor device are formed, wherein the N+ injection regions (111 and 113) in the second well region 105 and the third well region 106 are both connected to the cathode, and the P+ injection regions 122 and 123 and the N+ injection region 112 in the fourth well region 107 are all connected to the anode. The fifth well region 108 and the sixth well region 109 are floating without circuit connection to form the structure shown in FIG. 3. Here, the manufacturing processes of N+ injection region 111, N+ injection region 113, P+ injection region 122, P+ injection region 123 and the electrode layer above the N+ injection region 112 are omitted.

In addition, the present disclosure also provides an integrated circuit comprising the electrostatic discharge semiconductor device described in the above embodiments.

In summary, by using the electrostatic discharge semiconductor device, as well as the manufacturing method thereof and the integrated circuit of the embodiments of the present disclosure, only the second injection region is provided in the second well region and the third well region, without providing the first injection region, thereby saving a resistor structure in the SCR structure. Moreover, by setting up the floating fifth and sixth well regions to adjust the ion doping concentration in the first well region outside the fourth well region, the carrier migration efficiency on the device surface is reduced, the current amplification factor is reduced, and the holding voltage is increased. By adjusting the distance between the fifth well region (sixth well region) and the fourth well region, the avalanche breakdown voltage between the well regions can also be adjusted to regulate the triggering voltage of the device. Therefore, the electrostatic protection capability of electrostatic discharge semiconductor devices is enhanced, device size is reduced, and manufacturing processes are simplified. Furthermore, the shorter the distance between the fifth well region (sixth well region) and the fourth well region, the lower the avalanche breakdown voltage and the triggering voltage of the electrostatic discharge semiconductor device, and the better the device protection performance, making it suitable for electrostatic protection in the low voltage range.

Furthermore, a heavily doped buried layer is formed on the upper part of the substrate of the electrostatic discharge semiconductor device, so that a longitudinal SCR current discharge path (second current discharge path) can be formed on the basis of the original SCR transverse current discharge path (first current discharge path), which can improve the holding voltage of SCR conduction. Due to the heavy doping of the buried layer, the longitudinal second current discharge path gradually becomes the dominant current discharge path, achieving current discharge inside the device and avoiding the accumulation of discharge heat on the device surface. Moreover, the buried layer and substrate, as well as the second and third well regions and epitaxial layers, provide good internal and external isolation for the device, thus preventing leakage.

Furthermore, a first injection region is set up above the floating fifth and sixth well regions to increase the doping concentration within them, making the first current discharge path closer to the substrate, thereby extending the current discharge path and improving the holding voltage of the device.

Furthermore, the electrostatic discharge semiconductor device uses a dual interdigitated structure to achieve layout symmetry, which improves the device's failure current and enhances its electrostatic protection performance.

According to the embodiments of the present disclosure described above, these embodiments do not describe all details and do not limit the disclosure to only the specific embodiments described. Obviously, based on the above description, many modifications and changes can be made. This specification selects and specifically describes these embodiments in order to better explain the principles and practical applications of the present disclosure, so that those skilled in the art can make good use of the present disclosure and make modifications based on the present disclosure. The present disclosure is limited only by the claims and their full scope and equivalents.

What is claimed is:

1. An electrostatic discharge semiconductor device, comprising:
a substrate of a first doping type;
an epitaxial layer, located above the substrate;
a first well region of a first doping type, extending from a surface of the epitaxial layer to a surface of the substrate;
a second well region and a third well region of a second doping type, extending from the surface of the epitaxial layer to the surface of the substrate, and located on both sides of the first well region respectively and separated from the first well region;
a fourth well region of the second doping type, extending from a surface of the first well region to the internal and separated from the substrate;
a fifth well region and a sixth well region have a first doping type, extending from the surface of the first well region to the internal and separated from the substrate; the fifth well region and the sixth well region being symmetrically distributed on both sides of the fourth well region and separated from the fourth well region; and
a first injection region and a second injection region, spaced apart above the fourth well region, and having a first doping type and a second doping type, respectively,
wherein the second injection region is distributed in both the second well rejoin and the third well rejoin and connected to a cathode, and the first region and the second injection region in the fourth well region are connected to an anode.

2. The electrostatic discharge semiconductor device of claim 1, wherein an avalanche breakdown voltage between the fifth well region and the fourth well region decreases as the distance between the fifth well region and the fourth well region decreases;
an avalanche breakdown voltage between the sixth well region and the fourth well region decreases as the distance between the sixth well region and the fourth well region decreases;
a trigger voltage of the electrostatic discharge semiconductor device decreases as the distance between the fifth/sixth well region and the fourth well region decreases.

3. The electrostatic discharge semiconductor device of claim 1, wherein during operation of the electrostatic discharge semiconductor device, a controllable silicon structure comprising the first injection region in the fourth well region, the fourth well region, the first well region, the fifth well region and the sixth well region, the second well region and the third well region, and the second injection region in the second well region and the third well region is turned on to form a first current discharge path from the anode to the cathode.

4. The electrostatic discharge semiconductor device of claim 3, further comprising:
a buried layer of a second doping type, located in the upper part of the substrate and in contact with the first well region to the third well region; the first injection region having the highest doping concentration among all regions of the first doping type, while the second injection region having the highest doping concentration among all regions of the second doping type; the doping concentration of the buried layer being second only to the one with a higher doping concentration among the first injection region and the second injection region.

5. The electrostatic discharge semiconductor device of claim 4, wherein during operation of the electrostatic discharge semiconductor device, the controllable silicon structure comprising the first injection region in the fourth well region, the fourth well region, the first well region, the buried layer, the second well region and the third well region, and the second injection region in the second well region and the third well region is turned on to form a second current discharge path from the anode to the cathode.

6. The electrostatic discharge semiconductor device of claim 5, wherein when the electrostatic discharge semiconductor device receives an electrostatic pulse, the first current discharge path is turned on before the second current discharge path, and the current on the first current discharge path is smaller than the current on the second current discharge path.

7. The electrostatic discharge semiconductor device of claim 1, wherein the first injection region is distributed in both the fifth well region and the sixth well region, and the doping concentration of the first injection region in the fifth well region and the sixth well region is greater than the doping concentration of the fifth well region and the sixth well region, and the doping concentration of the fifth well region and the sixth well region is greater than the doping concentration of the first well region.

8. The electrostatic discharge semiconductor device of claim 1, further comprising:
a field oxide layer, distributed between the first injection region and the second injection region of each well region of the electrostatic discharge semiconductor device.

9. The electrostatic discharge semiconductor device of claim 1, wherein the electrostatic discharge semiconductor device is of a dual interdigitated structure.

10. The electrostatic discharge semiconductor device of claim 1, wherein the first doping type is P-type doping, while the second doping type is N-type doping.

11. A method for manufacturing an electrostatic discharge semiconductor device, comprising:
forming a substrate of a first doping type and a buried layer of a second doping type located in the upper part within the substrate;
forming an epitaxial layer located above the substrate, the epitaxial layer covering the buried layer;
forming a first well region of a first doping type extending inward from a surface of the epitaxial layer and extending to a surface of the buried layer;
forming a second well region and a third well region of a second doping type extending from the surface of the epitaxial layer to the interior and extending to the surface of the buried layer, the second well region and the third well region being located on both sides of the first well region and separated from the first well region, respectively;
forming a fourth well region of a second doping type extending inward from a surface of the first well region and separated from the buried layer;
forming a fifth well region and a sixth well region of a first doping type extending from the surface of the first well region to the interior and separated from the buried layer, the fifth well region and the sixth well region being symmetrically distributed on both sides of the fourth well region and separated from the fourth well region;
forming a plurality of spaced field oxide layers located above and outside the epitaxial layer; and
forming a plurality of spaced first injection regions and second injection regions located within each well region with the field oxide layer as an interval, and the first injection region and the second injection region are of the first doping type and the second doping type, respectively,
wherein, the second injection region is distributed in both the second well region and the third well region and connected to the cathode, and the first injection region and the second injection region in the fourth well region are both connected to the anode.
